(19) United States
(12) Patent Application Publication
(10) Pub. No.: US 2025/0226281 A1
(43) Pub. Date: Jul. 10, 2025

(54) SEMICONDUCTOR DEVICE

(71) Applicant: Rohm Co., Ltd., Kyoto-shi (JP)

(72) Inventor: Natsuya YOSHIDA, Kyoto-shi (JP)

(21) Appl. No.: 19/089,952

(22) Filed: Mar. 25, 2025

Related U.S. Application Data
(63) Continuation-in-part of application No. PCT/JP2023/036687, filed on Oct. 10, 2023.

(30) Foreign Application Priority Data
Oct. 24, 2022 (JP) 2022-169660

(51) Int. Cl. H01L 23/367; H01L 23/00; H01L 23/31; H01L 23/495

(52) U.S. Cl. CPC H01L 23/3677; H01L 23/49568; H01L 24/32; H01L 23/3107; H01L 2224/32245

(57) ABSTRACT

A semiconductor device comprises a heat dissipation member, an insulative layer, a conductive layer and a semiconductor element. The insulative layer is located on one side of the first direction with respect to the heat dissipation member and stacked on the heat dissipation member. The conductive layer is located on the opposite side of the heat dissipation member with respect to the insulative layer and bonded to the insulative layer. The semiconductor element is bonded to the conductive layer. The semiconductor element is electrically connected to the conductive layer. The insulative layer extends outside the conductive layer as viewed in the first direction.

### TECHNICAL FIELD

The present disclosure relates to a semiconductor device.

### BACKGROUND ART

WO-2017-094370-A1 discloses an example of a semiconductor device equipped with a cooler. The cooler includes a housing with a hollow region and a heat radiator. The housing has an opening provided leading to the hollow region. The heat radiator is attached to the housing so as to cover the opening. A part of the heat radiator is housed in the hollow region. The semiconductor device is bonded to a part of the heat radiator extending the outside the hollow region via a bonding material. When cooling water flows into the hollow region, the cooling water contacts the heat radiator. As a result, the semiconductor device may be cooled through the heat radiator.

In the heat radiator disclosed in WO-2017-094370-A1, a part of the heat radiator to which the bonding material is not applied is exposed to the outside. Hence, the creepage distance from the semiconductor device to the heat radiator is relatively short. Typically, the heat radiator contains metal. Therefore, the presence of the heat radiator may reduce the insulation withstand voltage of the semiconductor device.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1.

FIG. 3 is a plan view corresponding to FIG. 2, seen through the sealing resin.

FIG. 4 is a partially enlarged view of FIG. 3.

FIG. 5 is a plan view corresponding to FIG. 2, seen through the first conductive member and omitting the sealing resin and the second conductive member.

FIG. 6 is a right-side view of the semiconductor device shown in FIG. 1.

FIG. 7 is a bottom view of the semiconductor device shown in FIG. 1.

FIG. 8 is a cross-sectional view taken along a line VIII-VIII in FIG. 3.

FIG. 9 is a cross-sectional view taken along a line IX-IX line in FIG. 3.

FIG. 10 is a partially enlarged view of the first element and its surroundings shown in FIG. 9.

FIG. 11 is a partially enlarged view of the second element and its surroundings shown in FIG. 9.

FIG. 12 is a cross-sectional view taken along a line XII-XII in FIG. 3.

FIG. 13 is a cross-sectional view taken along a line XIII-XIII in FIG. 3.

FIG. 14 is a bottom view of a semiconductor device according to a second embodiment of the present disclosure.

FIG. 15 is a cross-sectional view taken along a line XV-XV in FIG. 14.

FIG. 16 is a cross-sectional view taken along a line XVI-XVI in FIG. 14.

FIG. 17 is a bottom view of a semiconductor device according to a third embodiment of the present disclosure.

FIG. 18 is a cross-sectional view taken along a line XVIII-XVIII in FIG. 17.

FIG. 19 is a cross-sectional view taken along a line XIX-XIX in FIG. 17.

FIG. 20 is a plan view of a semiconductor device according to a fourth embodiment of the present disclosure.

FIG. 21 is a right-side view of the semiconductor device shown in FIG. 20.

FIG. 22 is a cross-sectional view taken along a line XXII-XXII in FIG. 20.

FIG. 23 is a cross-sectional view taken along a line XXIII-XXIII in FIG. 20.

FIG. 24 is a partially enlarged view of FIG. 23.

### DETAILED DESCRIPTION OF EMBODIMENTS

The following describes preferred embodiments of the present disclosure in detail with reference to the drawings.

### First Embodiment

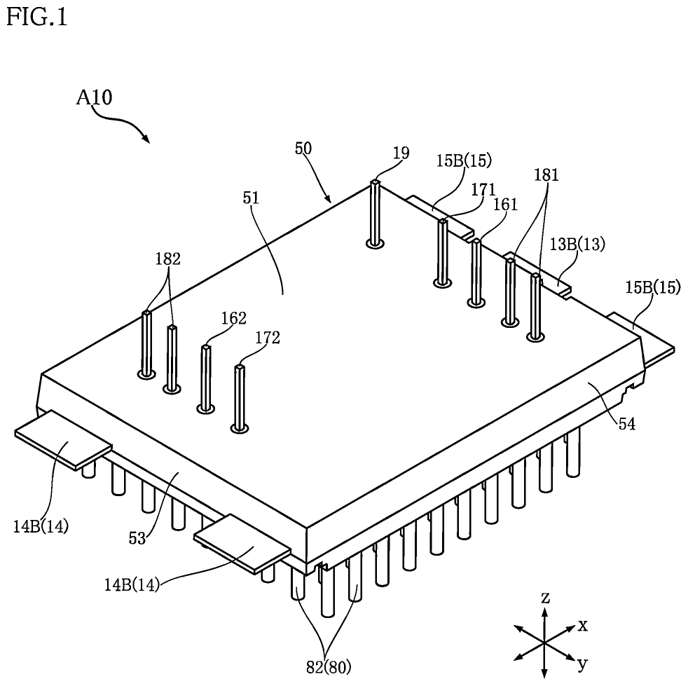

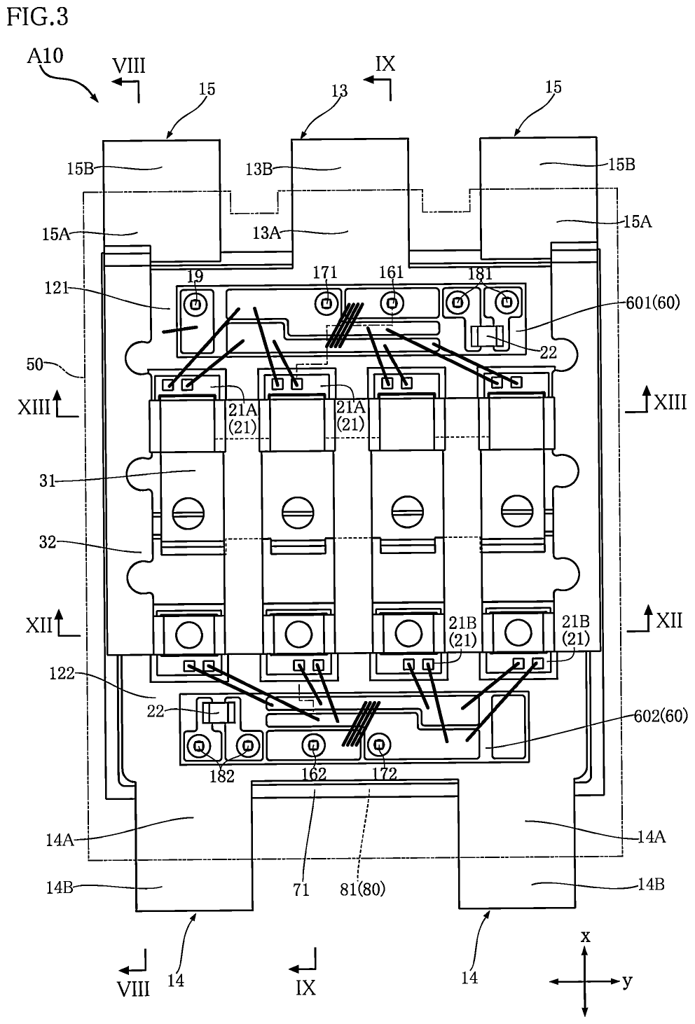

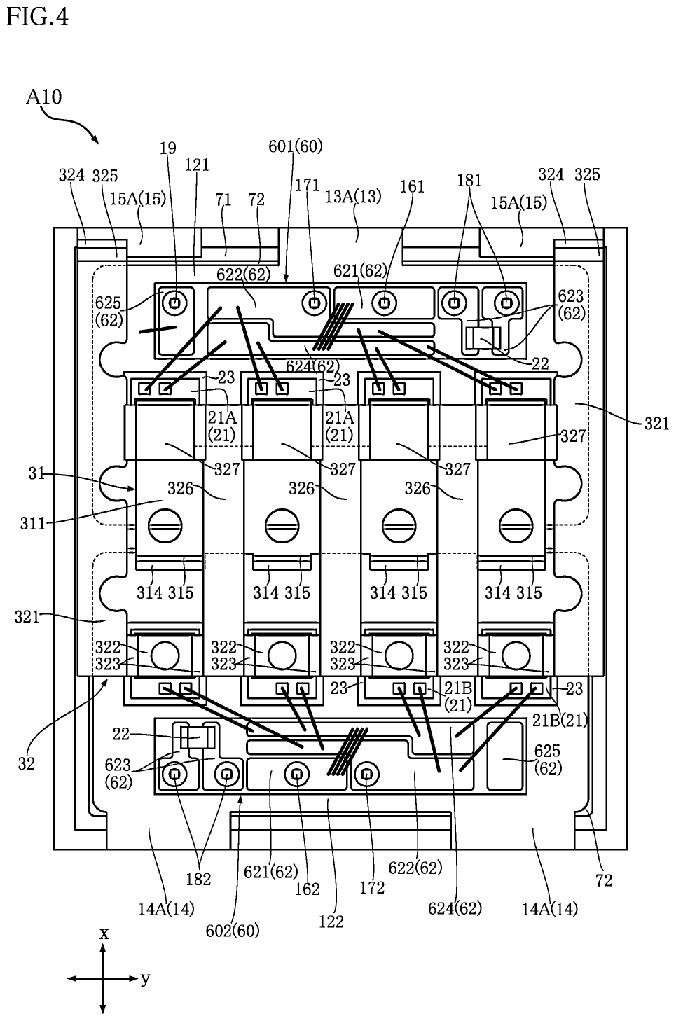

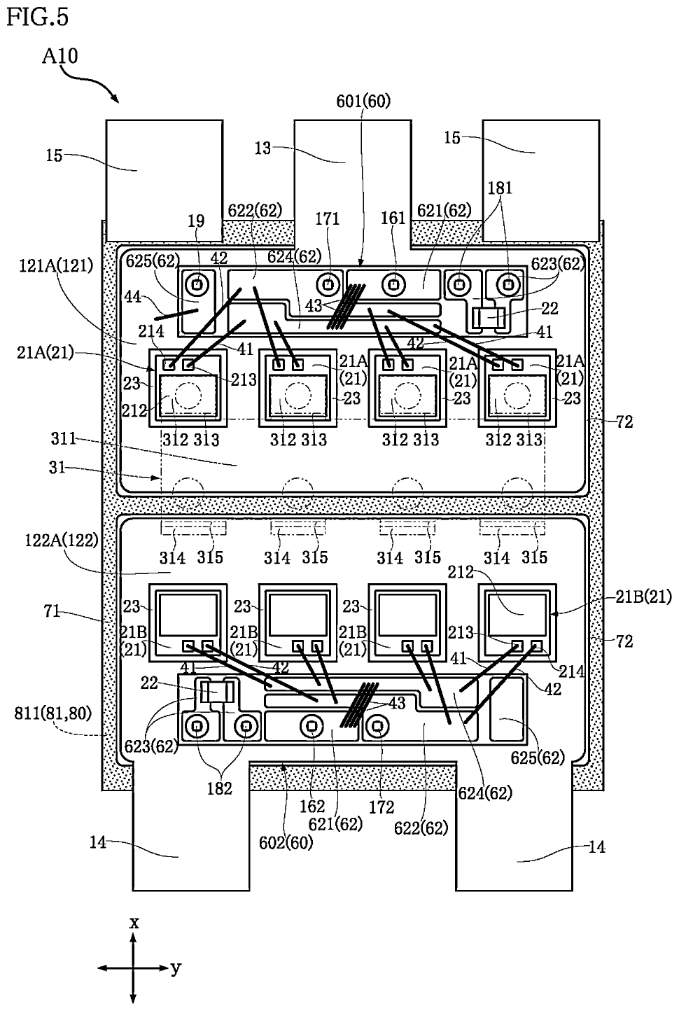

Based on FIGS. 1 to 13, a semiconductor device A10 according to a first embodiment of the present disclosure will be described. The semiconductor device A10 may comprise a heat dissipation member 80, an insulative layer 71, two metal layers 72, a bonding layer 73, a first conductive layer 121, a second conductive layer 122, a first input terminal 13, an output terminal 14, a second input terminal 15, a plurality of semiconductor elements 21, a first conductive member 31, a second conductive member 32 and a sealing resin 50. The semiconductor device A10 may comprise a first signal terminal 161, a second signal terminal 162, a third signal terminal 171, a fourth signal terminal 172, a pair of fifth signal terminals 181, a pair of sixth signal terminals 182, a seventh signal terminal 19, a pair of thermistors 22, and a pair of control wirings 60. For convenience of understanding, the sealing resin 50 is seen through in FIGS. 3 and 4. FIG. 3 shows the sealing resin 50 that is seen through as imaginary lines (double-dotted lines). For convenience of understanding, the first conductive member 31 is seen through and the second conductive member 32 and sealing resin 50 are omitted in FIG. 5. FIG. 3 shows the first conductive member 31 that is seen through as imaginary lines. In FIG. 3, a line IX-IX is shown as a single dotted line.

In the description of semiconductor device A10, a normal direction of the inner face 811 of the base portion 81 of the heat dissipation member 80 described later is referred to as a “first direction z”, for the sake of convenience. A direction orthogonal to the first direction z is referred to as a “second direction x”. A direction orthogonal to the first direction z and the second direction x is referred to as a “third direction y”.

The semiconductor device A10 may convert a DC power supply voltage applied to the first input terminal 13 and the second input terminal 15 into alternating power through the semiconductor elements 21. The converted alternating power output from the output terminal 14 may be supplied to a power supply target such as a motor.

The heat dissipation member 80 may be served as cooling the semiconductor device A10. The heat dissipation member 80 may be made of a material containing aluminum (Al), for example. In the present disclosure, the “material including aluminum” includes a material consisting solely of aluminum, aluminum-based material with an additive metal or the like, various aluminum alloys, and the like.

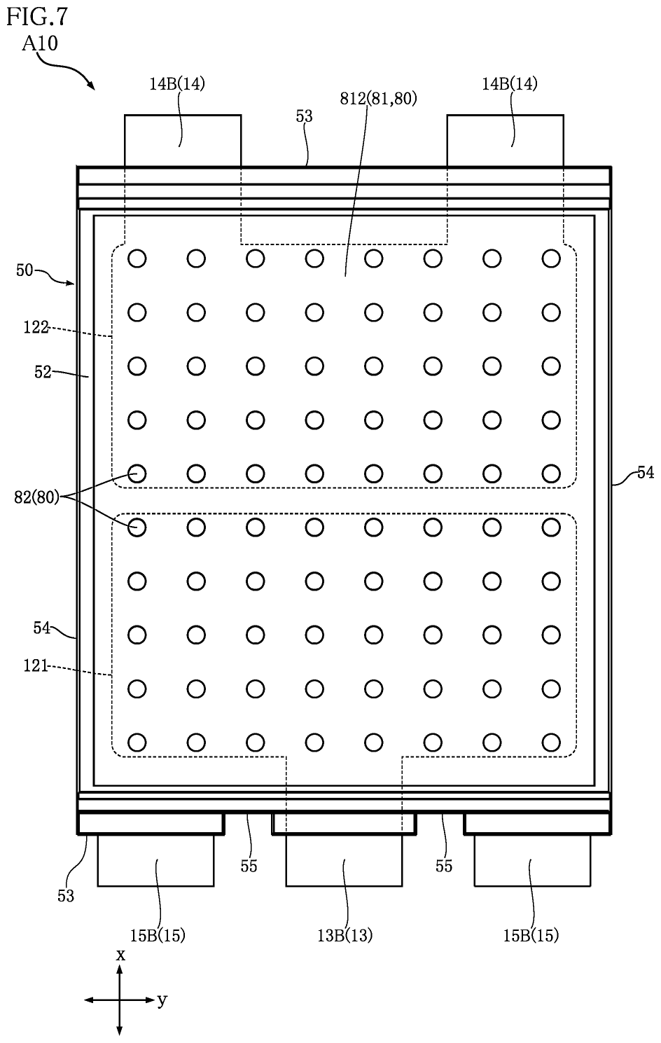

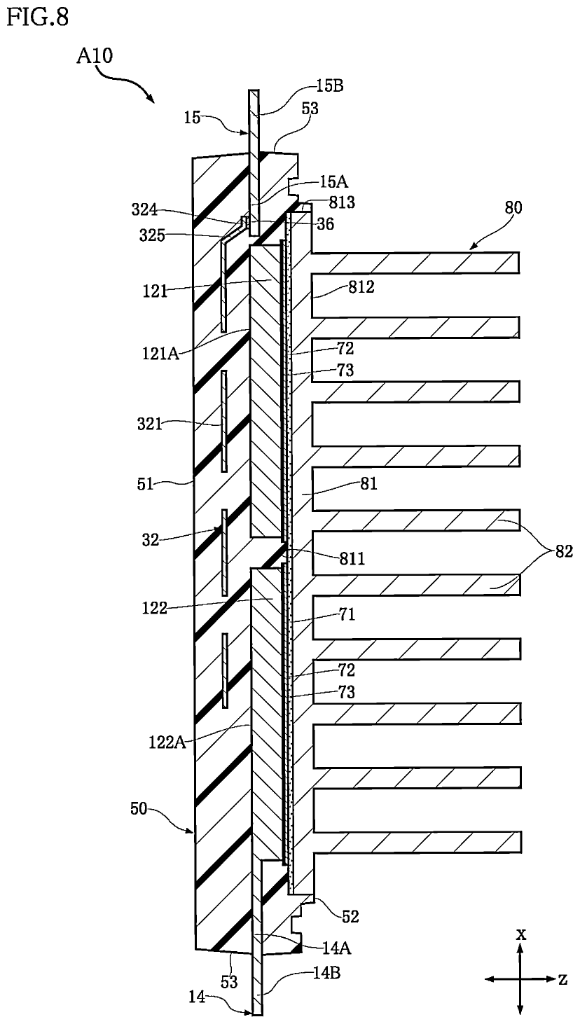

As shown in FIGS. 8, 9, 12, and 13, the heat dissipation member 80 may include a base portion 81 and a heat dissipating portion 82. The base portion 81 may be flat. The base portion 81 may include an inner face 811, an outer face 812, and an end face 813. The inner face 811 and the outer face 812 face away from each other in the first direction z. As shown in FIG. 7, the outer face 812 may be exposed externally from the sealing resin 50. The end face 813 faces the directions orthogonal to the first direction z. As viewed in the directions orthogonal to the first direction z, the sealing resin 50 may overlap with the end face 813. The end face 813 is covered by the sealing resin 50.

As shown in FIGS. 8, 9, 12, and 13, the heat dissipating portion 82 may be configured to protrude in the first direction z from the outer face 812 of the base portion 81. The heat dissipating portion 82 may be located opposite the insulative layer 71 with respect to the base portion 81 in the first direction z. As shown in FIG. 7, the heat dissipating portion 82 may be a plurality of pins spaced apart from each other in the directions orthogonal to the first direction z. As viewed in the first direction z, the heat dissipating portion 82 may overlap with each of the first conductive layer 121 and the second conductive layer 122.

As shown in FIGS. 8 to 13, the insulative layer 71 may be stacked on the inner face 811 of the base portion 81 of the heat dissipation member 80. Thus, the insulative layer 71 may be located on one side of the first direction z with respect to the heat dissipation member 80. The insulative layer 71 may be configured to be in contact with the base portion 81. As shown in FIG. 5, the insulative layer 71 may cover the entirety of the inner face 811. The insulative layer 71 may be made of a material containing resin. Alternatively, a material containing ceramics may be applied as the material of the insulative layer 71. The material of the insulative layer 71 may be a material with relatively high thermal conductivity. A dimension of the insulative layer 71 in the first direction z may be smaller than a dimension of the base portion 81 in the first direction z.

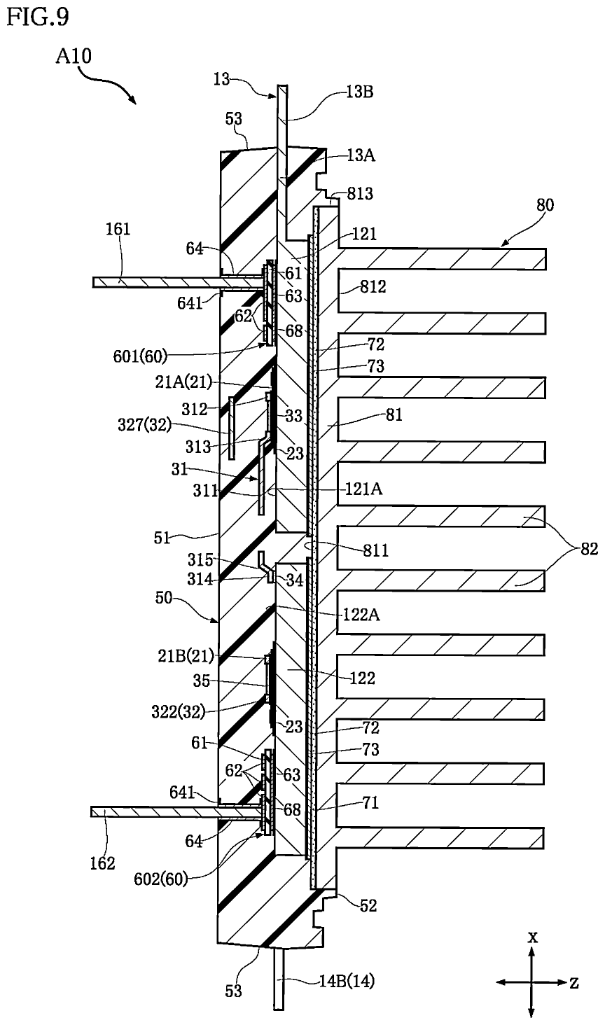

As shown in FIGS. 8 and 9, the two metal layers 72 may be stacked on the insulative layer 71. The two metal layers 72 may be each located on opposite side of the heat dissipation member 80 with respect to the insulative layer 71. The two metal layers 72 may be located apart from each other in the second direction x. The composition of the two metal layers 72 may include copper (Cu), for example.

As shown in FIGS. 8 to 11, the first conductive layer 121 and the second conductive layer 122 may each be located on opposite side of the heat dissipation member 80 with respect to the insulative layer 71. The first conductive layer 121 and the second conductive layer 122 may be bonded to the insulative layer 71 via the respective two metal layers 72. The composition of the first conductive layer 121 and the second conductive layer 122 may include copper. The first conductive layer 121 and the second conductive layer 122 may be located apart from each other in the second direction x. As shown in FIGS. 8 and 9, the first conductive layer 121 may include a first obverse face 121A facing the same side as the inner face 811 of the base portion 81 of the heat dissipation member 80 in the first direction z. As shown in FIGS. 8 and 9, the second conductive layer 122 may include a second obverse face 122A facing the same side as the first obverse face 121A in the first direction z.

As shown in FIGS. 8 to 11, the bonding layer 73 may be configured to bond the two metal layers 72, the first conductive layer 121 and the second conductive layer 122, respectively. The bonding layer 73 is, for example, solder. Alternatively, the bonding layer 73 may contain sintered body of metal particles.

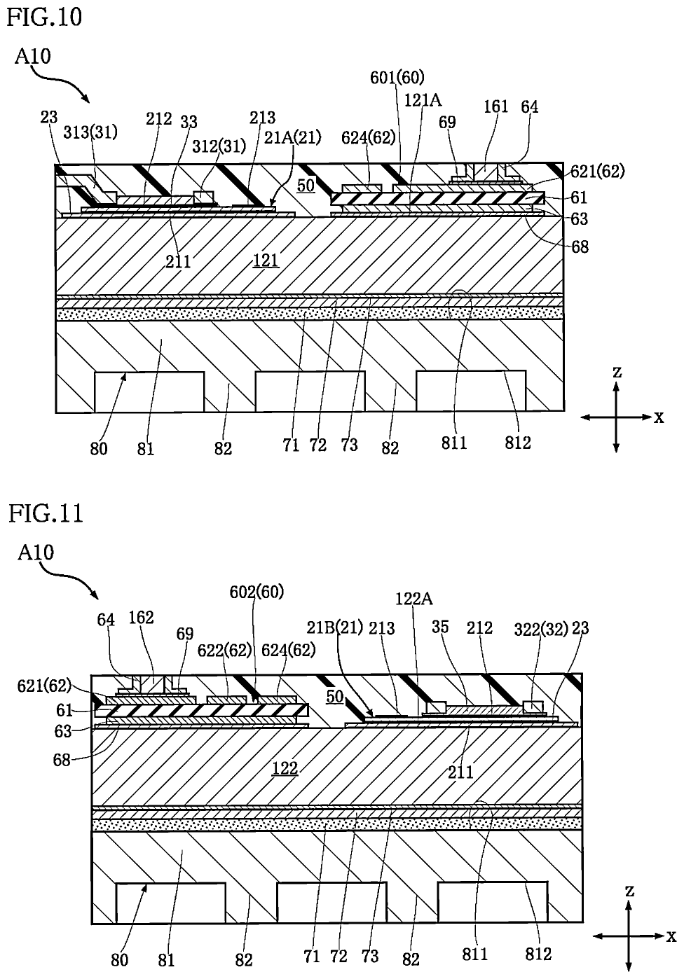

As shown in FIGS. 10 and 11, a dimension of each of the first conductive layer 121 and the second conductive layer 122 in the first direction z may be larger than the dimension of the insulative layer 71 in the first direction z. As shown in FIG. 5, as viewed in the first direction z, the insulative layer 71 may extend outside each of the first conductive layer 121 and the second conductive layer 122.

As shown in FIGS. 5 and 9, each of the semiconductor elements 21 may be mounted on either the first conductive layer 121 or the second conductive layer 122. The semiconductor elements 21 may each be, for example, MOSFET (Metal-Oxide-Semiconductor Field-Effect Transistors). Alternatively, the semiconductor elements 21 may each be switching element such as IGBT (Insulated Gate Bipolar Transistors) or diode. In the explanation of the semiconductor device A10, the semiconductor elements 21 are each n-channel MOSFET with a vertical structure. The semiconductor elements 21 may include a compound semiconductor substrate. The composition of the compound semiconductor substrate may include silicon carbide (SiC).

As shown in FIG. 5, in the semiconductor device A10, the semiconductor elements 21 may include a plurality of first elements 21A and a plurality of second elements 21B. The structure of each second element 21B may be identical to that of each first element 21A. The first elements 21A may be mounted on the first obverse face 121A of the first conductive layer 121. The first elements 21A may be located along the third direction y. The second elements 21B may be mounted on the second obverse face 122A of the second conductive layer 122. The second elements 21B may be located along the third direction y.

As shown in FIGS. 5, 10 and 11, the semiconductor elements 21 may each include a first electrode 211, a second electrode 212, a third electrode 213 and a fourth electrode 214.

As shown in FIGS. 10 and 11, each first electrode 211 may face either the first conductive layer 121 or the second conductive layer 122. The first electrode 211 may be configured to carry a current corresponding to the electric power prior to its conversion by the semiconductor element 21. In other words, the first electrode 211 may correspond to the drain electrode of the semiconductor element 21.

As shown in FIGS. 10 and 11, each second electrode 212 may be located on the opposite side of the first electrode 211 in the first direction z. The second electrode 212 may be configured to carry a current corresponding to the electric power after being converted by the semiconductor element 21. In other words, the second electrode 212 may correspond to the source electrode of the semiconductor element 21.

As shown in FIGS. 10 and 11, each third electrode 213 may be located on the same side as the second electrode 212 in the first direction z. The third electrode 213 may be applied a gate voltage to drive the semiconductor element 21. In other words, the third electrode 213 may correspond to the gate electrode of the semiconductor element 21. As shown in FIG. 5, the area of the third electrode 213 may be smaller than that of the second electrode 212 as viewed in the first direction z.

As shown in FIG. 5, each fourth electrode 214 may be located on the same side as the second electrode 212 in the first direction z and side by side with the third electrode 213 in the third direction y. The potential of the fourth electrode 214 may be configured to be equal to the potential of the second electrode 212.

As shown in FIGS. 10 and 11, the conductive bonding layer 23 may be interposed between either the first conductive layer 121 or the second conductive layer 122 and the first electrode 211 of one of the semiconductor elements 21. The conductive bonding layer 23 is, for example, solder. Alternatively, the conductive bonding layer 23 may contain sintered body of metal particles. The first electrodes 211 of the first elements 21A may be electrically bonded to the first obverse face 121A of the first conductive layer 121 via the respective conductive bonding layers 23. Hence, the first electrodes 211 of the first elements 21A may be electrically connected to the first conductive layer 121. The first electrodes 211 of the second elements 21B may be electrically bonded to the second obverse face 122A of the second conductive layer 122 via the respective conductive bonding layers 23. Hence, the first electrodes 211 of the second elements 21B may be electrically connected to the second conductive layer 122.

As shown in FIGS. 3 and 9, the first input terminal 13 may be located opposite the second conductive layer 122 with respect to the first conductive layer 121 in the second direction x, and connected to the first conductive layer 121. Hence, the first input terminal 13 may be electrically connected to the first electrodes 211 of the first elements 21A via the first conductive layer 121. The first input terminal 13 may be a P terminal (positive pole) to which a power conversion target such as a DC power supply voltage is applied. The first input terminal 13 may be configured to extend from the first conductive layer 121 in the second direction x. The first input terminal 13 may include a covered portion 13A and an exposed portion 13B. As shown in FIG. 9, the covered portion 13A may be connected to the first conductive layer 121 and covered by the sealing resin 50. The covered portion 13A may be flush with the first obverse face 121A of the first conductive layer 121. The exposed portion 13B may extend from the covered portion 13A in the second direction x and may be exposed from the sealing resin 50.

As shown in FIGS. 3 and 8, the output terminal 14 may be located opposite the first conductive layer 121 with respect to the second conductive layer 122 sandwiched in the second direction x, and connected to the second conductive layer 122. Hence, the output terminal 14 may be electrically connected to the first electrodes 211 of the second elements 21B via the second conductive layer 122. The output terminal 14 may output an AC power converted by the semiconductor elements 21. In the semiconductor device A10, the output terminal 14 may include a pair of regions spaced apart from each other in the third direction y. Alternatively, the output terminal 14 may be a single component without a pair of regions. The output terminal 14 may include a covered portion 14A and an exposed portion 14B. As shown in FIG. 8, the covered portion 14A may be connected to the second conductive layer 122 and covered by the sealing resin 50. The covered portion 14A may be flush with the second obverse face 122A of the second conductive layer 122. The exposed portion 14B may extend from the covered portion 14A in the second direction x and may be exposed from the sealing resin 50.

As shown in FIGS. 3 and 8, the second input terminal 15 may be located on the same side as the first input terminal 13 with respect to the first conductive layer 121 and the second conductive layer 122 in the second direction x, and spaced apart from the first conductive layer 121 and the second conductive layer 122. The second input terminal 15 may be electrically connected to the second electrodes 212 of the second elements 21B. The second input terminal 15 may be an N terminal (negative pole) to which a power conversion target such as a DC power supply voltage is applied. The second input terminal 15 may include a pair of regions spaced apart from each other in the third direction y. The first input terminal 13 may be located between these pair of regions in the third direction y. The second input terminal 15 may include a covered portion 15A and an exposed portion 15B. As shown in FIG. 8, the covered portion 15A may be spaced apart from the first conductive layer 121 and covered by the sealing resin 50. The exposed portion 15B may extend from the covered portion 15A in the second direction x and be exposed from the sealing resin 50.

The pair of control wirings 60 may form a prat of conductive paths between the first signal terminal 161, the second signal terminal 162, the third signal terminal 171, the fourth signal terminal 172, the pair of fifth signal terminals 181, the pair of sixth signal terminals 182 and the semiconductor elements 21. As shown in FIGS. 3 to 5, the pair of control wirings 60 may include a first wiring 601 and a second wiring 602. In the second direction x, the first wiring 601 may be located between the first elements 21A and the first input terminal 13 or the second input terminal 15. The first wiring 601 may be bonded to the first obverse face 121A of the first conductive layer 121. The first wiring 601 may form a part of the conductive path between the seventh signal terminal 19 and the first conductive layer 121. In the second direction x, the second wiring 602 may be located between the second elements 21B and the output terminal 14. The second wiring 602 may be bonded to the second obverse face 122A of the second conductive layer 122. As shown in FIGS. 10 and 11, the pair of control wirings 60 may each include an insulative layer 61, a plurality of wiring layers 62, a metal layer 63, and a plurality of sleeves 64. The pair of control wirings 60 may be covered by the sealing resin 50 except for a part of each sleeve 64.

As shown in FIGS. 10 and 11, the insulative layer 61 may include a portion interposed between the wiring layers 62 and the metal layer 63 in the first direction z. The insulative layer 61 may contain ceramics, for example. The insulative layer 61 may be configured to include an insulative resin sheet instead of ceramics.

As shown in FIGS. 10 and 11, the wiring layers 62 may be located on one side of the first direction z with respect to the insulative layer 61. The composition of the wiring layers 62 may include copper. As shown in FIG. 5, the wiring layers 62 may include a first wiring layer 621, a second wiring layer 622, a pair of third wiring layers 623, a fourth wiring layer 624, and a fifth wiring layer 625. The pair of third wiring layers 623 may be located next to each other in the third direction y.

As shown in FIGS. 10 and 11, the metal layer 63 may be located opposite the wiring layers 62 with respect to the insulative layer 61 in the first direction z. The composition of the metal layer 63 may include copper. The metal layer 63 of the first wiring 601 may be bonded to the first obverse face 121A of the first conductive layer 121 by a first adhesion layer 68. The metal layer 63 of the second wiring 602 may be bonded to the second obverse face 122A of the second conductive layer 122 by a first adhesion layer 68. The first adhesion layer 68 may be made of a conductive material or a non-conductive material. The first adhesion layer 68 may be made of solder, for example.

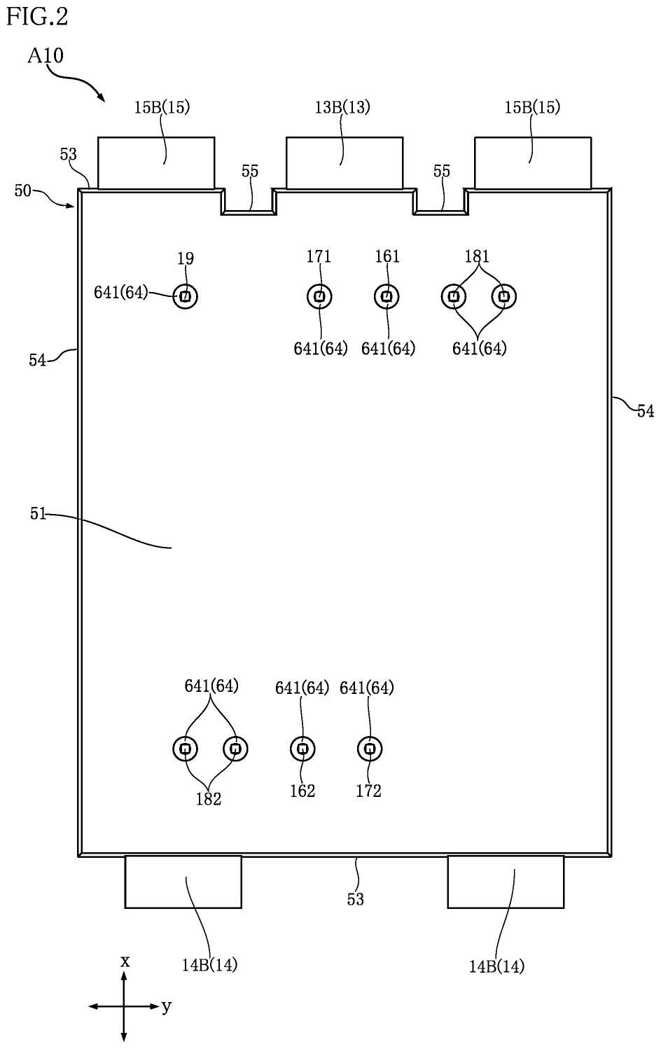

As shown in FIGS. 10 and 11, each of the sleeves 64 may be bonded to one of the wiring layers 62 by a second adhesion layer 69. The sleeves 64 may be made of a conductive material, such as a metal. Each of the sleeves 64 may have a cylindrical shape extending along the first direction z. One end of each sleeve 64 may be electrically bonded to one of the wiring layers 62. As shown in FIGS. 2 and 9, an end face 641 corresponding to the other end of each sleeve 64 may be exposed from the top face 51 of the sealing resin 50 as described below. The second adhesion layer 69 may be conductive. The second adhesion layer 69 is solder, for example.

As shown in FIG. 4, one of the pair of thermistors 22 may be electrically bonded to the pair of third wiring layers 623 of the first wiring 601. As shown in FIG. 4, the other of the pair of thermistors 22 may be electrically bonded to the pair of third wiring layers 623 of the second wiring 602. The pair of thermistors 22 may be, for example, NTC (Negative Temperature Coefficient) thermistors. NTC thermistors may be characterized by a gradual decrease in resistance as the temperature rises. The pair of thermistors 22 may be used as a sensor for detecting the temperature of the semiconductor device A10.

As shown in FIG. 1, the first signal terminal 161, the second signal terminal 162, the third signal terminal 171, the fourth signal terminal 172, the pair of fifth signal terminals 181, the pair of sixth signal terminals 182, and the seventh signal terminal 19 may be formed by metal pins extending in the first direction z. These terminals may protrude from the top face 51 of the sealing resin 50 as described below. These terminals may be individually press-fitted into the respective sleeves 64 of the pair of control wirings 60. Hence, each of these terminals may be supported by one of the sleeves 64 and may be electrically connected to one of the wiring layers 62.

As shown in FIGS. 5 and 10, the first signal terminal 161 may be press-fitted into the sleeve 64 bonded to the first wiring layer 621 of the first wiring 601 among the sleeves 64 of the pair of control wirings 60. Hence, the first signal terminal 161 may be supported by the relevant sleeve 64 and electrically connected to the first wiring layer 621 of the first wiring 601. The first signal terminal 161 may be electrically connected to the third electrodes 213 of the first elements 21A. The first signal terminal 161 may receive a gate voltage to drive the first elements 21A.

As shown in FIGS. 5 and 11, the second signal terminal 162 may be press-fitted into the sleeve 64 bonded to the first wiring layer 621 of the second wiring 602 among the sleeves 64 of the pair of control wirings 60. Hence, the second signal terminal 162 may be supported by the relevant sleeve 64 and electrically connected to the first wiring layer 621 of the second wiring 602. The second signal terminal 162 may be electrically connected to the third electrode 213 of the second elements 21B. The second signal terminal 162 may receive a gate voltage to drive the second elements 21B.

As shown in FIG. 2, the third signal terminal 171 may be located next to the first signal terminal 161 in the third direction y. As shown in FIG. 5, the third signal terminal 171 may be press-fitted into the sleeve 64 bonded to the second wiring layer 622 of the first wiring 601 among the sleeves 64 of the pair of control wirings 60. Hence, the third signal terminal 171 may be supported by the relevant sleeve 64 and electrically connected to the second wiring layer 622 of the first wiring 601. The third signal terminal 171 may be electrically connected to the fourth electrodes 214 of the first elements 21A. The third signal terminal 171 may receive a voltage corresponding to the maximum current among the currents flowing to the fourth electrodes 214 of the first element 21A.

As shown in FIG. 2, the fourth signal terminal 172 may be located next to the second signal terminal 162 in the third direction y. As shown in FIG. 5, the fourth signal terminal 172 may be press-fitted into the sleeve 64 bonded to the second wiring layer 622 of the second wiring 602 among the sleeves 64 of the pair of control wirings 60. Hence, the fourth signal terminal 172 may be supported by the relevant sleeve 64 and electrically connected to the second wiring layer 622 of the second wiring 602. The fourth signal terminal 172 may be electrically connected to the fourth electrodes 214 of the second elements 21B. The fourth signal terminal 172 may receive a voltage corresponding to the maximum current among the currents flowing to the fourth electrodes 214 of the second elements 21B.

As shown in FIG. 2, the pair of fifth signal terminals 181 may be located opposite the third signal terminal 171 with respect to the first signal terminal 161 in the third direction y. The pair of fifth signal terminals 181 may be located next to each other in the third direction y. As shown in FIG. 5, the pair of fifth signal terminals 181 may be individually press-fitted into a pair of sleeves 64 bonded to the pair of third wiring layers 623 of the first wiring 601 among the sleeves 64 of the pair of control wirings 60. Hence, the pair of fifth signal terminals 181 may be supported by the pair of sleeves 64 and electrically connected to the pair of third wiring layers 623 of the first wiring 601. The pair of fifth signal terminals 181 may be electrically connected to the thermistor 22 electrically bonded to the pair of third wiring layers 623 of the first wiring 601 among the pair of thermistors 22.

As shown in FIG. 2, the pair of sixth signal terminals 182 may be located opposite the fourth signal terminal 172 with respect to the second signal terminal 162 in the third direction y. The pair of sixth signal terminals 182 may be located next to each other in the third direction y. As shown in FIG. 5, the pair of sixth signal terminals 182 may be individually press-fitted into a pair of sleeves 64 bonded to the pair of third wiring layers 623 of the second wiring 602 among the sleeves 64 of the pair of control wirings 60. Hence, the pair of sixth signal terminals 182 may be supported by the pair of sleeves 64 and electrically connected to the pair of third wiring layers 623 of the second wiring 602. The pair of sixth signal terminals 182 may be electrically connected to the thermistor 22 electrically bonded to the pair of third wiring layers 623 of the second wiring 602 among the pair of thermistors 22.

As shown in FIG. 2, the seventh signal terminal 19 may be located on the opposite side of the first signal terminal 161 with respect to the third signal terminal 171 in the third direction y. As shown in FIG. 5, the seventh signal terminal 19 may be press-fitted into the sleeve 64 bonded to the fifth wiring layer 625 of the first wiring 601 among the sleeves 64 of the pair of control wirings 60. Hence, the seventh signal terminal 19 may be supported by the relevant sleeve 64 and electrically connected to the fifth wiring layer 625 of the first wiring 601. The seventh signal terminal 19 may be electrically connected to the first conductive layer 121. The seventh signal terminal 19 may receive a voltage corresponding to the DC power input to the first input terminal 13 and the second input terminal 15.

As shown in FIG. 5, the first wires 41 may be electrically bonded to the respective third electrodes 213 of the first elements 21A and the fourth wiring layer 624 of the first wiring 601. As shown in FIG. 5, the third wires 43 may be electrically bonded to the fourth wiring layer 624 of the first wiring 601 and the first wiring layer 621 of the first wiring 601. Hence, the first signal terminal 161 may be electrically connected to the third electrodes 213 of the first elements 21A. The composition of the first wires 41 and the third wires 43 may include gold (Au). Alternatively, the composition of the first wires 41 and the third wires 43 may include copper or aluminum.

As shown in FIG. 5, the first wires 41 may be electrically connected to the respective third electrodes 213 of the second elements 21B and the fourth wiring layer 624 of the second wiring 602. As shown in FIG. 5, the third wires 43 may be electrically bonded to the fourth wiring layer 624 of the second wiring 602 and the first wiring layer 621 of the second wiring 602. Hence, the second signal terminal 162 may be electrically connected to the third electrodes 213 of the second elements 21B.

As shown in FIG. 5, the second wires 42 may be electrically bonded to the respective fourth electrodes 214 of the first elements 21A and the second wiring layer 622 of the first wiring 601. Hence, the third signal terminal 171 may be electrically connected to the fourth electrodes 214 of the first elements 21A. As shown in FIG. 5, the second wires 42 may be electrically bonded to the fourth electrodes 214 of the second elements 21B and the second wiring layer 622 of the second wiring 602. Hence, the fourth signal terminal 172 may be electrically connected to the fourth electrodes 214 of the second elements 21B. The composition of the second wires 42 may include gold. Alternatively, the composition of the second wires 42 may include copper or aluminum.

As shown in FIG. 5, the fourth wire 44 may be electrically bonded to the fifth wiring layer 625 of the first wiring 601 and the first obverse face 121A of the first conductive layer 121. Hence, the seventh signal terminal 19 may be electrically connected to the first conductive layer 121. The composition of the fourth wire 44 may include gold. Alternatively, the composition of the fourth wire 44 may include copper or aluminum.

As shown in FIGS. 5 and 10, the first conductive member 31 may be electrically bonded to the second electrodes 212 of the first elements 21A and the second obverse face 122A of the second conductive layer 122. Hence, the second electrodes 212 of the first elements 21A may be electrically connected to the second conductive layer 122. The composition of the first conductive member 31 may include copper. The first conductive member 31 may be a metal clip. As shown in FIG. 5, the first conductive member 31 may include a body portion 311, a plurality of first bonding portions 312, a plurality of first coupling portions 313, second bonding portions 314, and second coupling portions 315.

The body portion 311 may be a main part of the first conductive member 31. As shown in FIG. 5, the body portion 311 may extend in the third direction y. As shown in FIG. 9, the body portion 311 may be configured to bridge the gap between the first conductive layer 121 and the second conductive layer 122.

As shown in FIG. 10, the first bonding portions 312 may be individually bonded to the second electrodes 212 of the first elements 21A. Each of the first bonding portions 312 may face the second electrode 212 of one of the first elements 21A.

As shown in FIG. 5, the first coupling portions 313 may be connected to the body portion 311 and the respective first bonding portions 312. The first coupling portions 313 may be spaced apart from each other in the third direction y. As shown in FIG. 9, the first coupling portions 313 may be inclined away from the first obverse face 121A of the first conductive layer 121 from the respective first bonding portions 312 toward the body portion 311, as viewed in the third direction y.

As shown in FIGS. 5 and 9, the second bonding portions 314 may be bonded to the second obverse face 122A of the second conductive layer 122. The second bonding portions 314 may face the second obverse face 122A. The second bonding portions 314 may extend in the third direction y. A dimension of the second bonding portion 314 in the third direction y may be configured to be equal to a dimension of the body portion 311 in the third direction y.

As shown in FIGS. 5 and 9, the second coupling portions 315 may be connected to the body portion 311 and the second bonding portions 314. As viewed in the third direction y, the second coupling portions 315 may be inclined away from the second obverse face 122A of the second conductive layer 122 from the second bonding portions 314 toward the body portion 311. A dimension of the second coupling portions 315 in the third direction y may be configured to be equal to the dimension of the body portion 311 in the third direction y.

As shown in FIGS. 9, 10 and 13, the semiconductor device A10 may include first conductive bonding layers 33. The first conductive bonding layers 33 may be interposed between the respective second electrodes 212 of the first elements 21A and the respective first bonding portions 312. The first conductive bonding layers 33 may electrically bond the second electrodes 212 of the first elements 21A and the first bonding portions 312 to each other. The first conductive bonding layer 33 is solder, for example. Alternatively, the first conductive bonding layer 33 may contain sintered body of metal particles.

As shown in FIG. 9, the semiconductor device A10 may include second conductive bonding layers 34. The second conductive bonding layers 34 may be interposed between the second obverse face 122A of the second conductive layer 122 and the second bonding portions 314. The second conductive bonding layers 34 may electrically bond the second obverse face 122A and the second bonding portions 314 to each other. The second conductive bonding layers 34 are solder, for example. Alternatively, the second conductive bonding layer 34 may contain sintered body of metal particles.

As shown in FIGS. 4 and 11, the second conductive member 32 may be electrically bonded to the second electrodes 212 of the second elements 21B and the covered portion 15A of the second input terminal 15. Hence, the second electrodes 212 of the second elements 21B may be electrically connected to the second input terminal 15. The composition of the second conductive member 32 may include copper. The second conductive member 32 may be a metal clip. As shown in FIG. 4, the second conductive member 32 may include a pair of body portions 321, a plurality of third bonding portions 322, a plurality of third coupling portions 323, a pair of fourth bonding portions 324, a pair of fourth coupling portions 325, a plurality of intermediate portions 326, and a plurality of beam portions 327.

As shown in FIG. 4, the pair of body portions 321 may be spaced apart from each other in the third direction y. The pair of body portions 321 may extend in the second direction x. As shown in FIG. 8, the pair of body portions 321 may be located parallel to the first obverse face 121A of the first conductive layer 121 and the second obverse face 122A of the second conductive layer 122. The pair of body portions 321 may be further spaced away from the first obverse face 121A and the second obverse face 122A than the body portion 311 of the first conductive member 31.

As shown in FIG. 4, the intermediate portions 326 may be spaced apart from each other in the third direction y, and located between the pair of body portions 321 in the third direction y. The intermediate portions 326 may extend in the second direction x. A dimension of each of the intermediate portions 326 in the second direction x may be smaller than a dimension of each of the pair of body portions 321 in the second direction x.

As shown in FIG. 11, the third bonding portions 322 may be individually bonded to the second electrodes 212 of the second elements 21B. Each of the third bonding portions 322 may face the second electrode 212 of one of the second elements 21B.

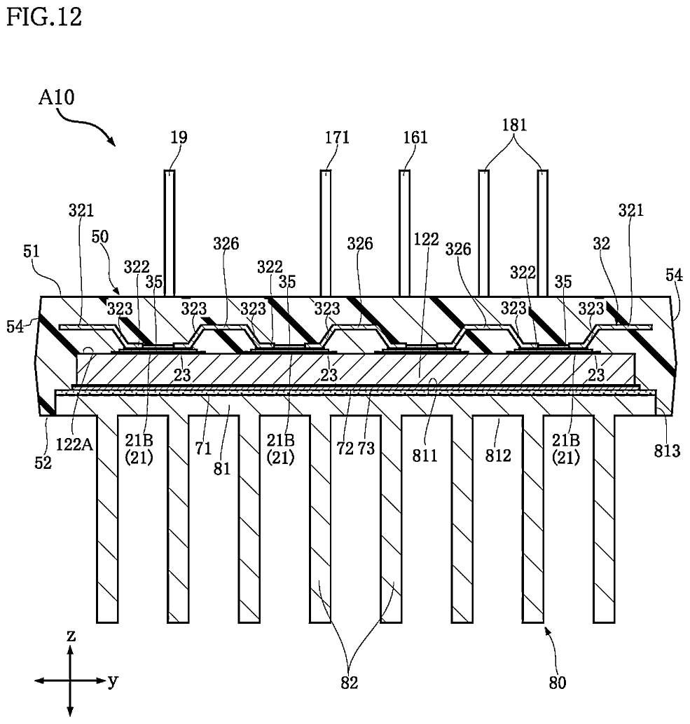

As shown in FIGS. 4 and 12, the third coupling portions 323 may be connected to both sides in the third direction y of each third bonding portion 322. Each third coupling portion 323 may be connected to one of the body portions 321 and intermediate portions 326. As viewed in the second direction x, each of the third coupling portions 323 may be inclined away from the second obverse face 122A of the second conductive layer 122 from one of the third bonding portions 322 toward one of the body portions 321 and intermediate portions 326.

As shown in FIGS. 4 and 8, the pair of fourth bonding portions 324 may be bonded to the covered portion 15A of the second input terminal 15. The pair of fourth bonding portions 324 may face the covered portion 15A.

As shown in FIGS. 4 and 8, the pair of fourth coupling portions 325 may be connected to the respective body portions 321 and fourth bonding portions 324. As viewed in the third direction y, each of the fourth coupling portions 325 may be inclined away from the first obverse face 121A of the first conductive layer 121 from the relevant fourth bonding portion 324 toward the relevant body portion 321.

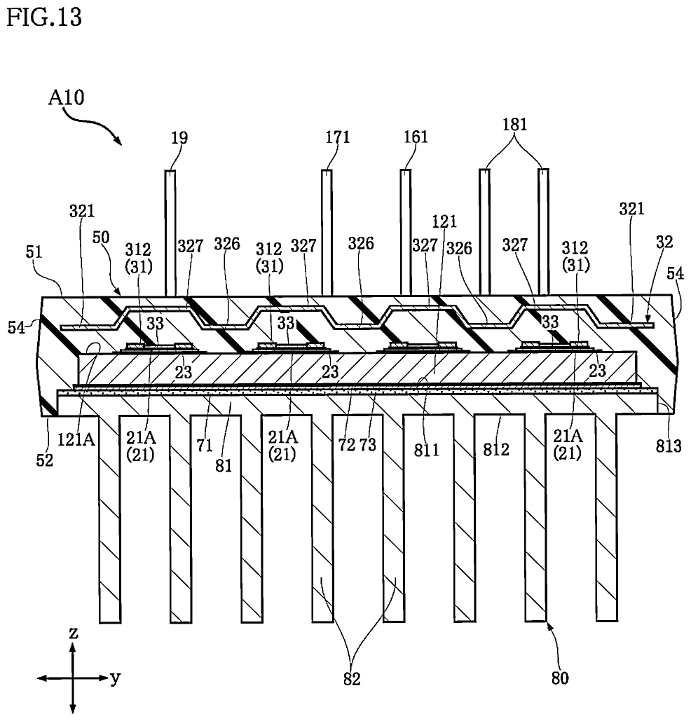

As shown in FIGS. 4 and 13, the beam portions 327 may be located along the third direction y. As viewed in the first direction z, the beam portions 327 may include parts individually overlapping with the first bonding portion 312 of the first conductive member 31. The beam portions 327 located in the middle area in the second direction y are connected on its both sides in the second direction y to the intermediate portions 326. Each of the remaining two beam portions 327 is connected on one side in the second direction y to one of the body portions 321 and on the other side in the second direction y to one of the intermediate portions 326. As viewed in the second direction x, the beam portions 327 may protrude toward the side that the first obverse surface 121A of the first conductive layer 121 faces in the first direction z.

As shown in FIGS. 9, 11 and 12, the semiconductor device A10 may include third conductive bonding layers 35. The third conductive bonding layers 35 may be interposed between the respective second electrodes 212 of the second elements 21B and third bonding portions 322. The third conductive bonding layers 35 may electrically bond the second electrodes 212 of the second elements 21B and the third bonding portions 322 to each other. The third conductive bonding layers 35 are solder, for example. Alternatively, the third conductive bonding layers 35 may contain sintered body of metal particles.

As shown in FIG. 8, the semiconductor device A10 may include fourth conductive bonding layers 36. The fourth conductive bonding layers 36 may be interposed between the covered portion 15A of the second input terminal 15 and the pair of fourth bonding portions 324. The fourth conductive bonding layers 36 may electrically bond the covered portion 15A and the respective fourth bonding portions 324 to each other. The fourth conductive bonding layers 36 are solder, for example. Alternatively, the fourth conductive bonding layers 36 may contain sintered body of metal particles.

As shown in FIGS. 8, 9, 12, and 13, the sealing resin 50 may cover the first conductive layer 121, the second conductive layer 122, the semiconductor elements 21, the first conductive member 31, and the second conductive member 32. The sealing resin 50 may cover at least a part of the insulative layer 71. The sealing resin 50 may further cover a part of each of the first input terminal 13, the output terminal 14, and the second input terminal 15. The sealing resin 50 may be insulative. The sealing resin 50 may be made of a material containing a black epoxy resin, for example. As shown in FIGS. 2 and 6 to 9, the sealing resin 50 may include a top face 51, a bottom face 52, a pair of first side faces 53, a pair of second side faces 54, and a pair of recesses 55.

As shown in FIGS. 8 and 9, the top face 51 may face the same side as the first obverse face 121A of the first conductive layer 121 in the first direction z. As shown in FIGS. 8 and 9, the bottom face 52 may face away from the top face 51 in the first direction z. As shown in FIG. 7, the outer face 812 of the base portion 81 of the heat dissipation member 80 may be exposed from the bottom face 52.

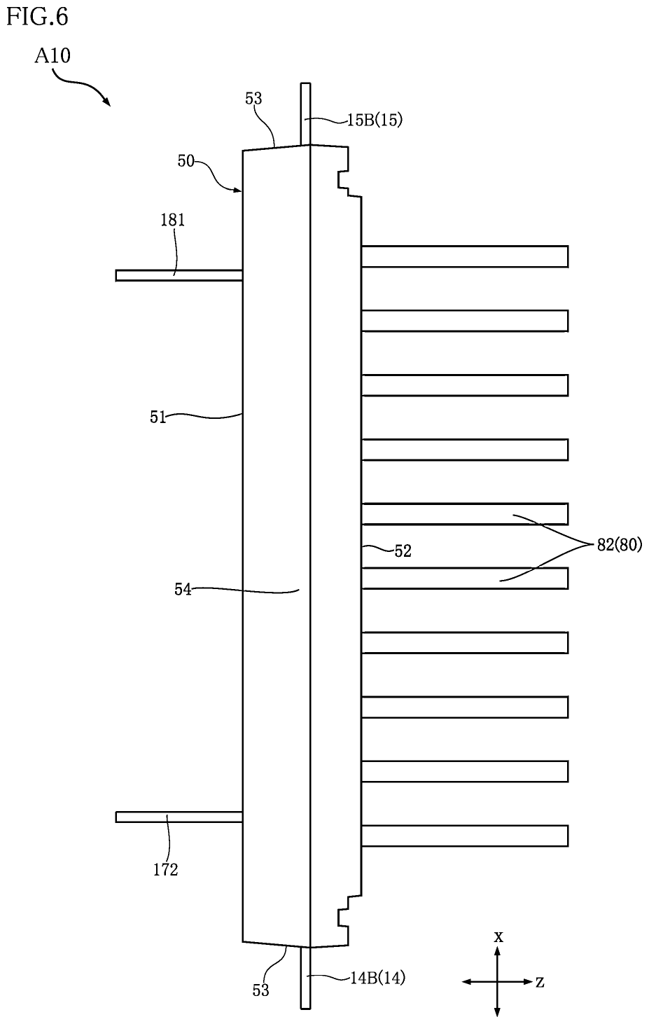

As shown in FIGS. 2 and 6, the pair of first side faces 53 may be spaced apart from each other in the second direction x. The pair of first side faces 53 may face the second direction x and extend in the third direction y. The pair of first side faces 53 may be connected to the top face 51. The exposed portion 13B of the first input terminal 13 and the exposed portion 15B of the second input terminal 15 may be exposed from one of the pair of first side faces 53. The exposed portion 14B of the output terminal 14 may be exposed from the other of the pair of first side faces 53.

As shown in FIGS. 2 and 7, the pair of second side faces 54 may be spaced apart from each other in the third direction y. The pair of second side faces 54 may face away from each other in the third direction y and extend in the second direction x. The pair of second side faces 54 may be connected to the top face 51 and the bottom face 52.

As shown in FIGS. 2 and 7, the pair of recesses 55 may be recessed in the second direction x from the first side face 53 at which the exposed portion 13B of the first input terminal 13 and the exposed portion 15B of the second input terminal 15 are exposed among the pair of first side faces 53. The pair of recesses 55 may be configured to extend from the top face 51 to the bottom face 52 in the first direction z. The pair of recesses 55 may be located on both sides in the third direction y of the first input terminal 13.

Next, operative effects of the semiconductor device A10 will be described.

The semiconductor device A10 may include the heat dissipation member 80, the insulative layer 71 stacked on the heat dissipation member 80, the first conductive layer 121 located on the opposite side of the heat dissipation member 80 with respect to the insulative layer 71 and bonded to the insulative layer 71, and the semiconductor element 21 bonded to the first conductive layer 121. The semiconductor element 21 may be electrically connected to the first conductive layer 121. The insulative layer 71 may be located on one side of the first direction z with respect to the heat dissipation member 80. The insulative layer 71 may extend outside the first conductive layer 121 as viewed in the first direction z. Such a configuration may allow heat emitted from the semiconductor element 21 to be conducted to the heat dissipation member 80 through the first conductive layer 121 and the insulative layer 71. On that basis, the creepage distances from the first conductive layer 121 to the heat dissipation member 80 may be increased. Therefore, such a configuration in the semiconductor device A10 improve the insulation withstand voltage of the semiconductor device A10.

According to the configuration in which the insulative layer 71 extends outside the first conductive layer 121 as viewed in the first direction z, the insulative layer 71 may block the leakage current from the first conductive layer 121 to the heat dissipation member 80.

The insulative layer 71 may be in contact with the heat dissipation member 80. Such a configuration may allow heat reaching the insulative layer 71 to be conducted more quickly to the heat dissipation member 80.

The semiconductor device A10 may include the sealing resin 50 covering the first conductive layer 121 and the semiconductor element 21. The sealing resin 50 may cover at least a part of the insulative layer 71. In this case, the insulative layer 71 may be made of a material containing resin. Such a configuration enhances the affinity between the sealing resin 50 and the insulative layer 71, thereby increasing the bonding strength of the insulative layer 71 to the sealing resin 50. This helps prevent the detachment of the heat dissipation member 80 from the sealing resin 50.

The heat dissipation member 80 may include the base portion 81 with which the insulative layer 71 is in contact and the heat dissipating portion 82 located on the opposite side of the insulative layer 71 with respect to the base portion 81 and protruding in the first direction z from the base portion 81. Such a configuration increases the surface area of the heat dissipation member 80 that is exposed externally. This improves the heat dissipation performance of the heat dissipation member 80.

The insulative layer 71 may cover the entirety of the inner face 811 of the base portion 81. According to such a configuration, the creepage distance from the first conductive layer 121 to the heat dissipation member 80 may be uniformly increased with respect to the sections extending in directions orthogonal to the first direction z. This helps prevent a local decrease in the insulation withstand voltage of the semiconductor device A10.

The dimension of the first conductive layer 121 in the first direction z may be larger than the dimension of the insulative layer 71 in the first direction z. Such a configuration facilitates heat diffusion in the first conductive layer 121 in directions orthogonal to the first direction z. This reduces the thermal resistance of the first conductive layer 121 in the first direction z.

The semiconductor device A10 may include the metal layer 72 stacked on the insulative layer 71 and the bonding layer 73 bonding the metal layer 72 and the first conductive layer 121. Such a configuration may help the first conductive layer 121 to be firmly bonded to the insulative layer 71 even when the insulative layer 71 is made of a non-metallic material.

The dimension of the insulative layer 71 in the first direction z may be smaller than the dimension of the base portion 81 in the first direction z. Such a configuration may reduce the excessive dimension of the semiconductor device A10 in the first direction z.

### Second Embodiment

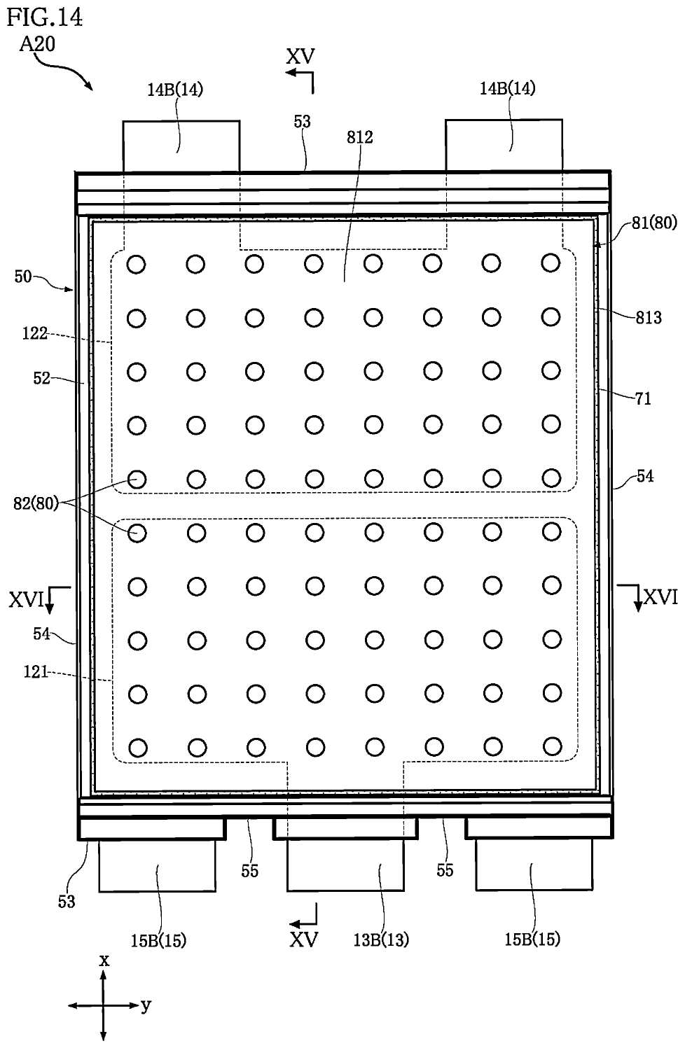

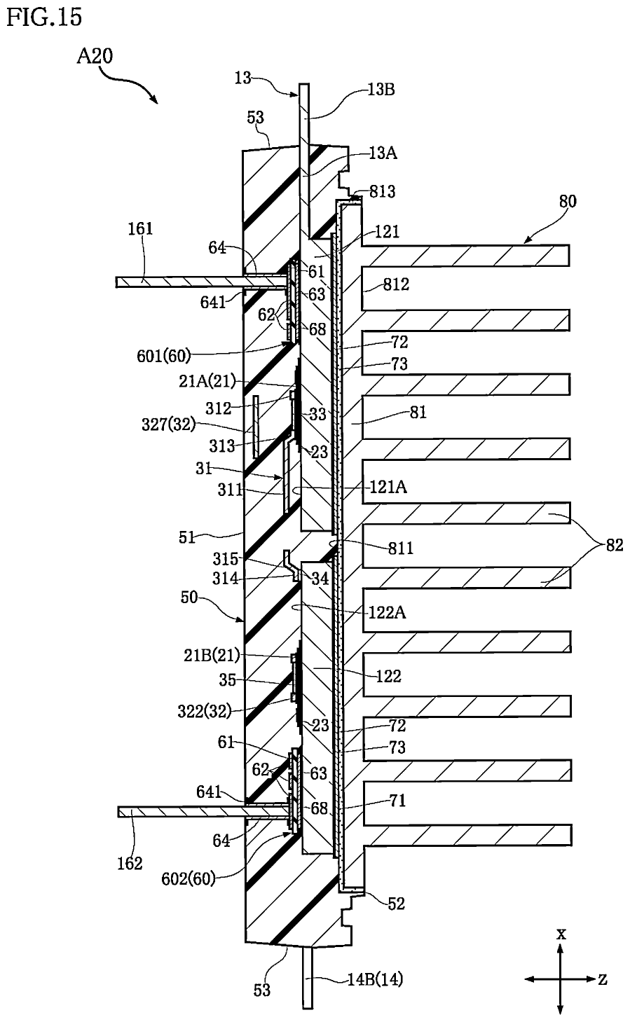

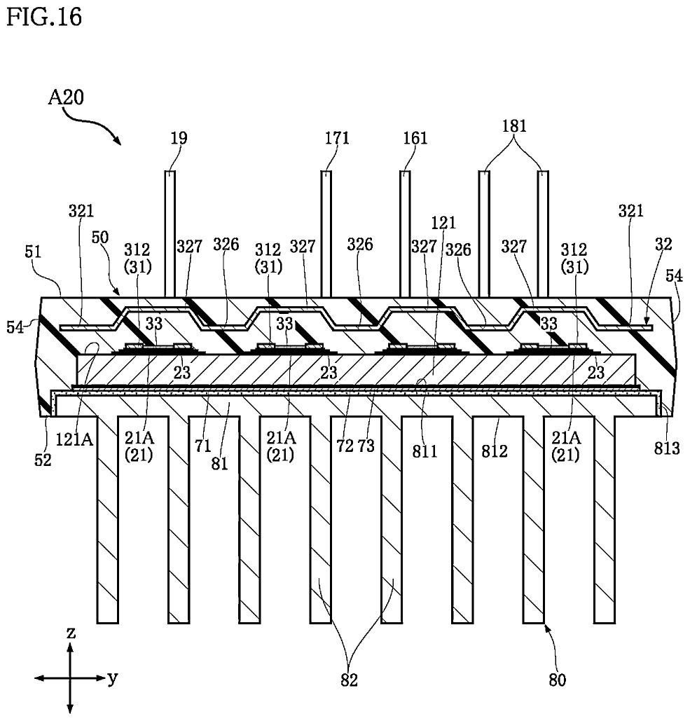

Based on FIGS. 14 to 16, a semiconductor device A20 according to a second embodiment of the present disclosure is described. In these figures, the same or similar elements as those of the semiconductor device A10 described above are denoted by the same reference signs, and overlapping descriptions are omitted.

In the semiconductor device A20, the configuration of the insulative layer 71 may differ from that of the semiconductor device A10.

As shown in FIGS. 14 to 16, the insulative layer 71 may cover the end face 813 of the base portion 81 of the heat dissipation member 80. The part of the insulative layer 71 covering the end face 813 may be covered by the sealing resin 50.

Next, operative effects of the semiconductor device A20 will be described.

The semiconductor device A20 may include the heat dissipation member 80, the insulative layer 71 stacked on the heat dissipation member 80, the first conductive layer 121 located on the opposite side of the heat dissipation member 80 with respect to the insulative layer 71 and bonded to the insulative layer 71, and the semiconductor element 21 bonded to the first conductive layer 121. The semiconductor element 21 may be electrically connected to the first conductive layer 121. The insulative layer 71 may be located on one side of the first direction z with respect to the heat dissipation member 80. The insulative layer 71 may extend outside the first conductive layer 121 as viewed in the first direction z. Therefore, such a configuration in the semiconductor device A20 improve the insulation withstand voltage of the semiconductor device A20. The semiconductor device A20 may have a configuration in common with the semiconductor device A10, thereby achieving the same effect as the semiconductor device A10.

In the semiconductor device A20, the insulative layer 71 may cover the end face 813 of base portion 81 of heat dissipation member 80. Such a configuration may increase the creepage distances from the first conductive layer 121 to the heat dissipation member 80 compared to the semiconductor device A10. This more effectively enhances the insulation withstand voltage of the semiconductor device A20.

### Third Embodiment

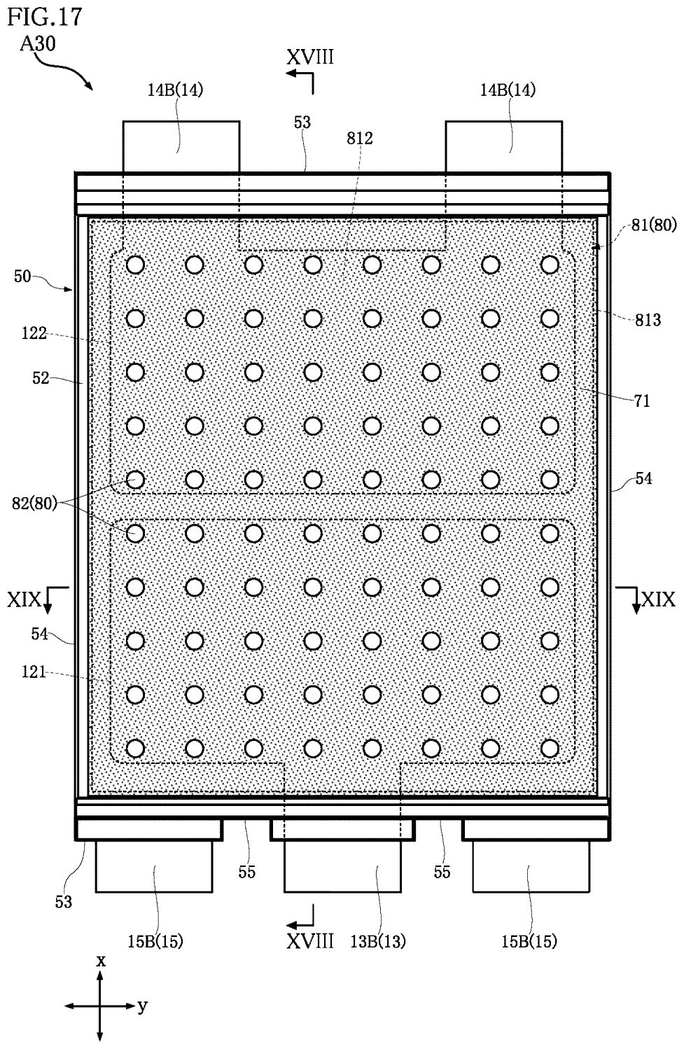

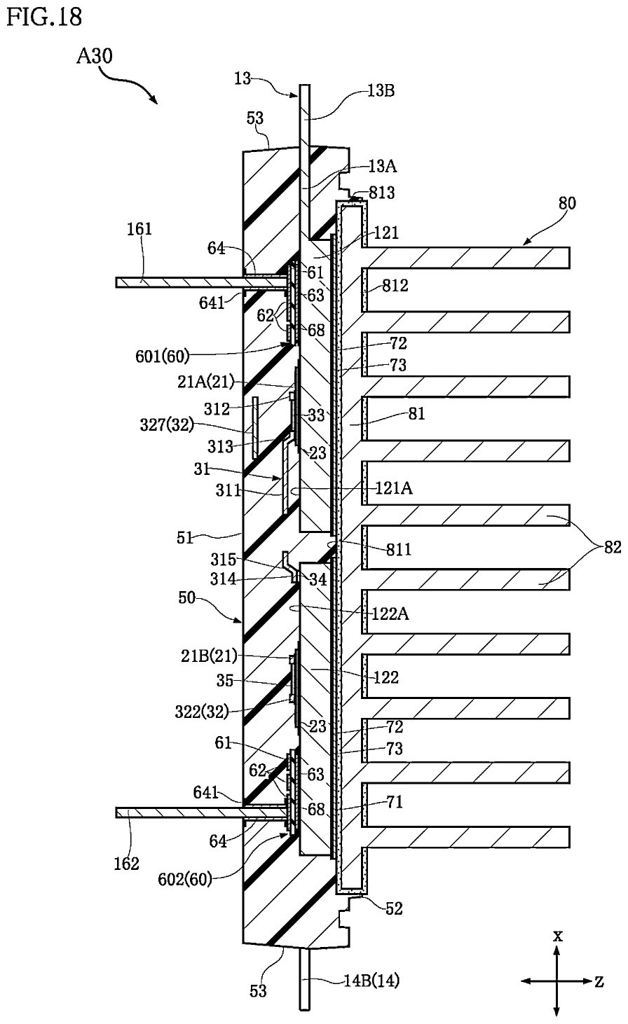

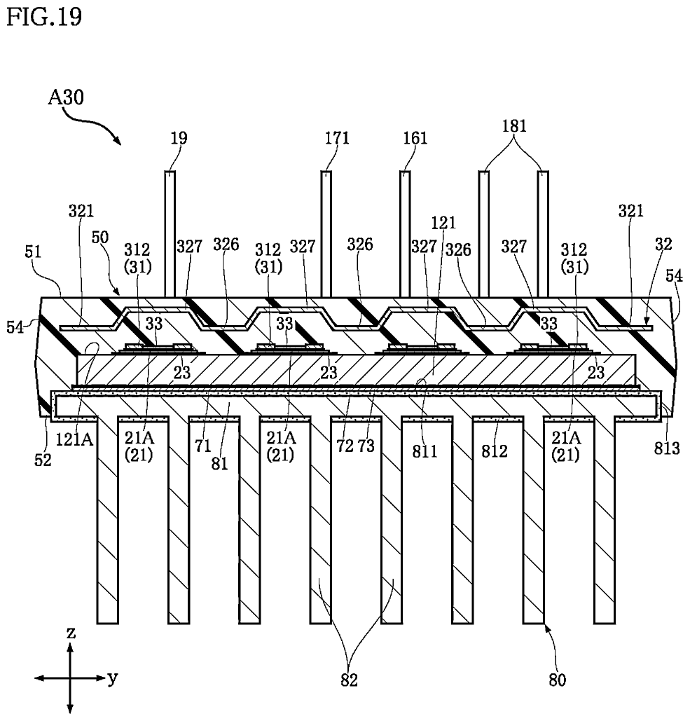

Based on FIGS. 17 to 19, a semiconductor device A30 according to a third embodiment of the present disclosure is described. In these figures, the same or similar elements as those of the semiconductor device A10 described above are denoted by the same reference signs, and overlapping descriptions are omitted.

In the semiconductor device A30, the configuration of the insulative layer 71 may differ from that of the semiconductor device A10.

As shown in FIGS. 17 to 19, the insulative layer 71 may cover the end face 813 and the outer face 812 of the base portion 81 of the heat dissipation member 80. The part of the insulative layer 71 covering the end face 813 is covered by the sealing resin 50. The part of the insulative layer 71 covering the outer face 812 may be exposed externally from the sealing resin 50.

Next, operative effects of the semiconductor device A30 will be described.

The semiconductor device A30 may include the heat dissipation member 80, the insulative layer 71 stacked on the heat dissipation member 80, the first conductive layer 121 located on the opposite side of the heat dissipation member 80 with respect to the insulative layer 71 and bonded to the insulative layer 71, and the semiconductor element 21 bonded to the first conductive layer 121. The semiconductor element 21 may be electrically connected to the first conductive layer 121. The insulative layer 71 may be located on one side of the first direction z with respect to the heat dissipation member 80. The insulative layer 71 may extend outside the first conductive layer 121 as viewed in the first direction z. Therefore, such a configuration in the semiconductor device A30 improve the insulation withstand voltage of the semiconductor device A30. The semiconductor device A30 may have a configuration in common with the semiconductor device A10, thereby achieving the same effect as the semiconductor device A10.

In the semiconductor device A30, the insulative layer 71 may cover the end face 813 and the outer face 812 of the base portion 81 of the heat dissipation member 80. Such a configuration may increase the creepage distances from the first conductive layer 121 to the heat dissipation member 80 compared to the semiconductor device A20. This more effectively enhances the insulation withstand voltage of the semiconductor device A30.

### Fourth Embodiment

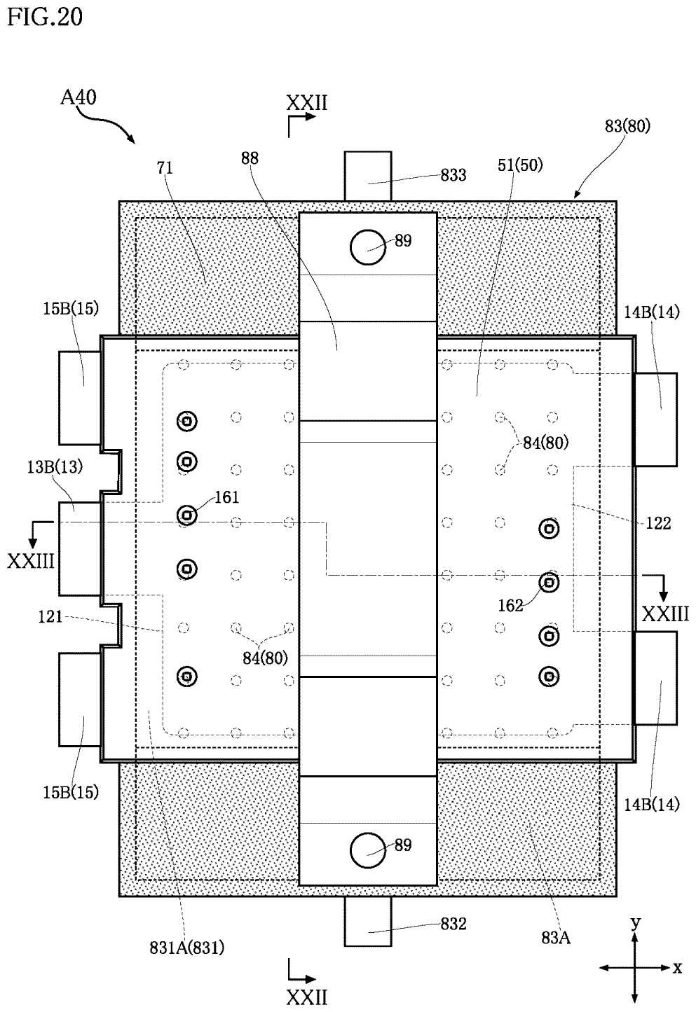

Based on FIGS. 20 to 24, a semiconductor device A40 according to a fourth embodiment of the present disclosure is described. In these figures, the same or similar elements as those of the semiconductor device A10 described above are denoted by the same reference signs, and overlapping descriptions are omitted.

The semiconductor device A40 may differ in the configuration of the heat dissipation member 80 from that of the semiconductor device A10. The semiconductor device A40 may include a base material 11 and an attachment member 88 instead of the two metal layers 72 and the bonding layer 73.

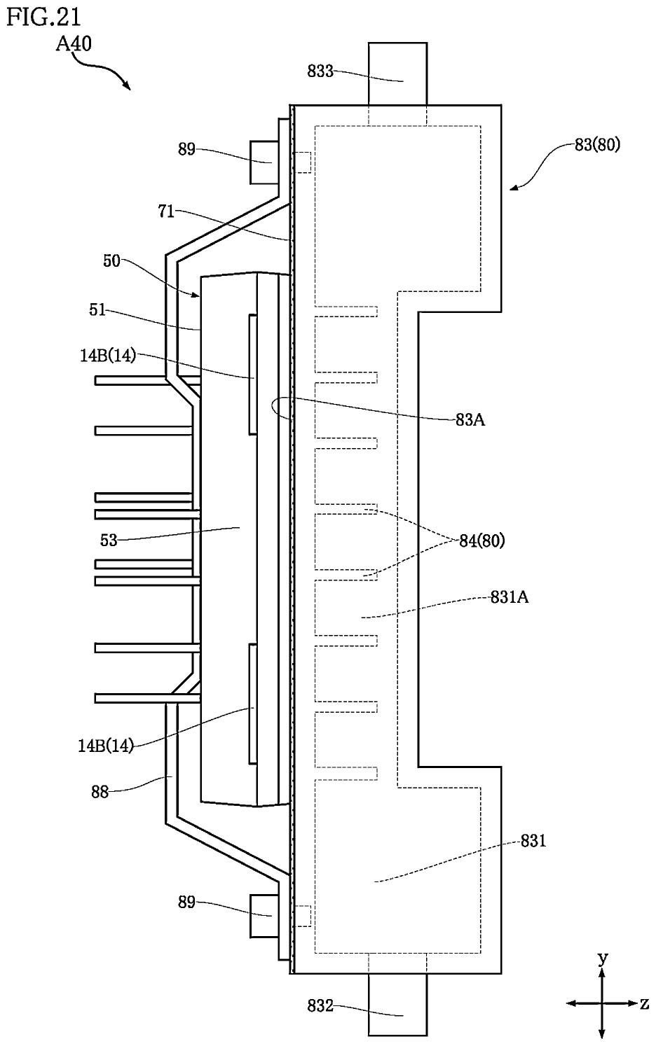

As shown in FIGS. 21 to 23, the heat dissipation member 80 may include a housing 83 and a heat dissipation body 84 instead of the base portion 81 and the heat dissipating portion 82. The housing 83 may include a hollow portion 831, an inlet 832, and an outlet 833. The hollow portion 831 may be located inside the housing 83. The inlet 832 and the outlet 833 may be connected to the hollow portion 831. The inlet 832 and the outlet 833 may be located opposite each other in the third direction y with respect to the hollow portion 831. The heat dissipation member 80 may be configured so that cooling water flows from the inlet 832 through the hollow portion 831 to the outlet 833.

As shown in FIGS. 21 to 23, the housing 83 may include a mounting face 83A facing the first direction z. The mounting face 83A may face the first conductive layer 121 and the second conductive layer 122. As shown in FIG. 20, the insulative layer 71 may cover the entirety of the mounting face 83A.

As shown in FIGS. 21 to 23, the hollow portion 831 of the housing 83 may include a narrowing portion 831A. The narrowing portion 831A refers to a part of the hollow portion 831 with the minimum cross-sectional area between the inlet 832 and the outlet 833 in a direction orthogonal to the first direction z.

As shown in FIGS. 21 to 23, the heat dissipation body 84 may be accommodated in the narrowing portion 831A of the hollow portion 831 of the housing 83. The heat dissipation body 84 may be connected to the housing 83. As shown in FIG. 20, the heat dissipation body 84 may be a plurality of pins spaced apart from each other in directions orthogonal to the first direction z.

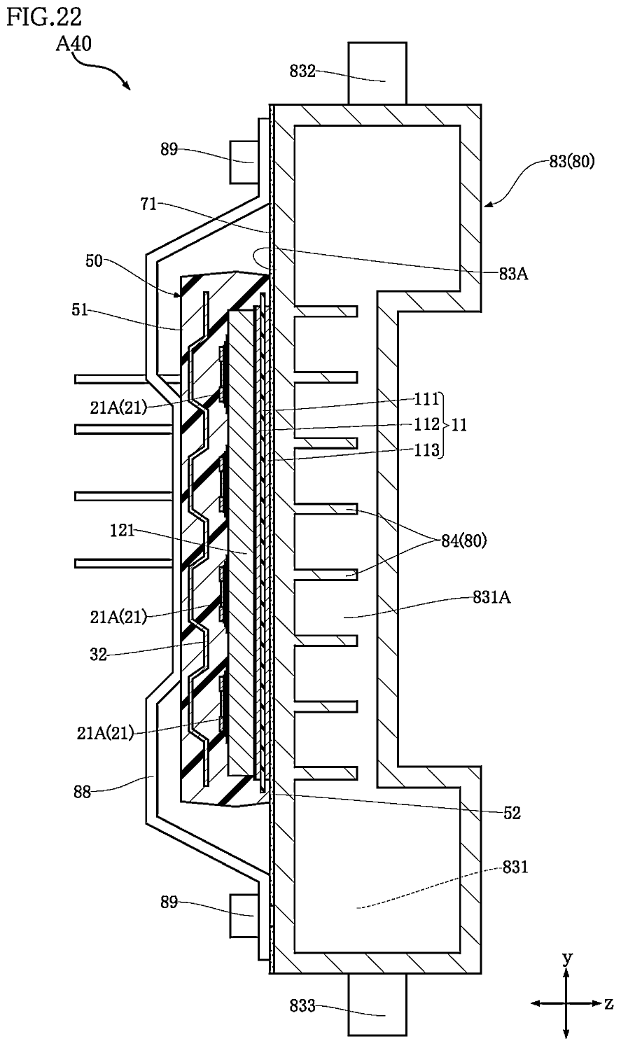

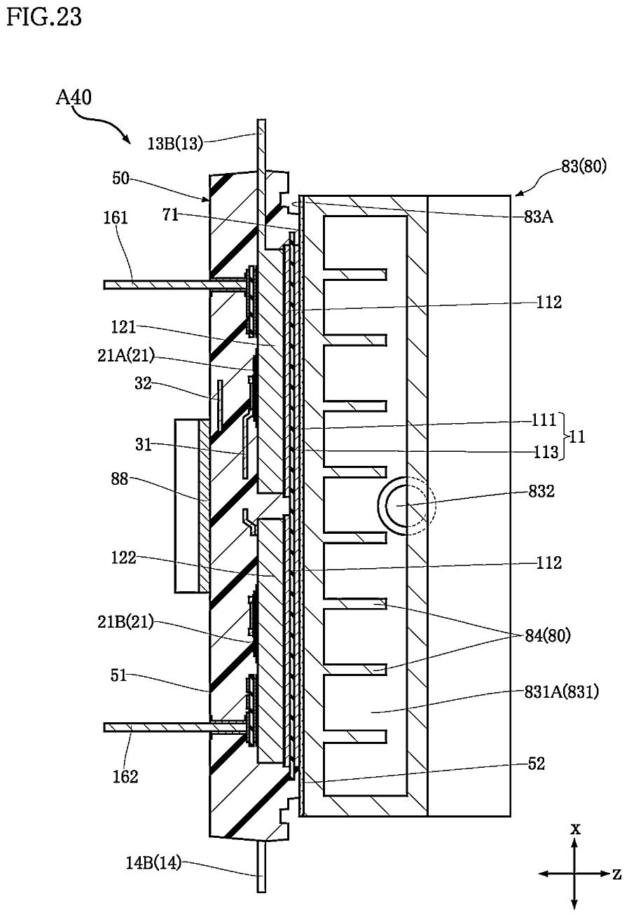

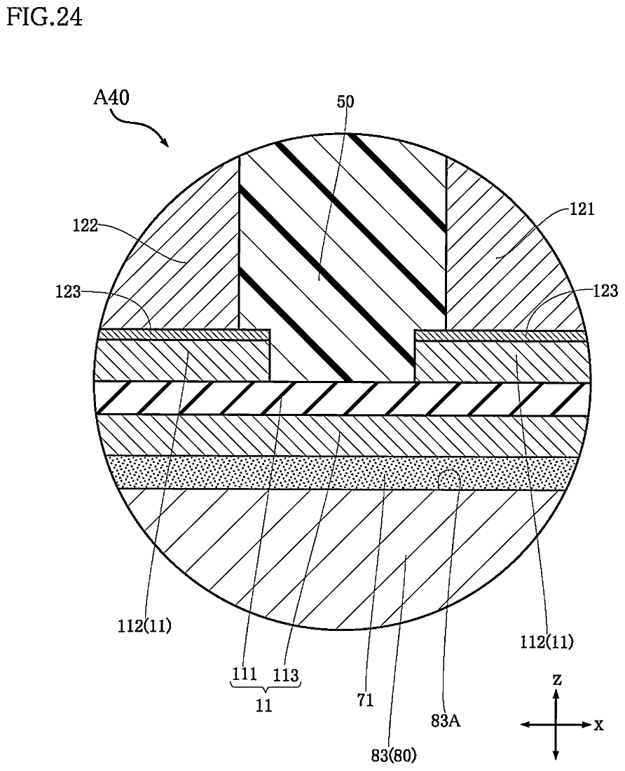

As shown in FIGS. 22 and 23, the base material 11 may be located opposite the semiconductor elements 21 with respect to the first conductive layer 121 and the second conductive layer 122 in the first direction z. The base material 11 may support the first conductive layer 121 and the second conductive layer 122. The base material 11 may be formed from a DBC (Direct Bonded Copper) substrate. As shown in FIGS. 23 and 24, the base material 11 may include an insulative layer 111, two metal layers 112, and a heat dissipation layer 113. The base material 11 may be covered by the sealing resin 50 except for a part of the heat dissipation layer 113.

As shown in FIGS. 23 and 24, the insulative layer 111 may include a portion interposed between the two metal layers 112 and the heat dissipation layer 113 in the first direction z. The insulative layer 111 may be made of a material with relatively high thermal conductivity. The insulative layer 111 may be made of ceramics including aluminum nitride (AlN), for example. Instead of ceramics, the insulative layer 111 may be composed of an insulating resin sheet. The dimension of the insulative layer 111 in the first direction z may be smaller than the dimension of each of the first conductive layer 121 and the second conductive layer 122 in the first direction z.

As shown in FIGS. 23 and 24, the two metal layers 112 may each be located between the insulative layer 111 and the first conductive layer 121 or the second conductive layer 122 in the first direction z. The two metal layers 112 may be spaced apart from each other in the second direction x. The composition of the two metal layers 112 may include copper. As viewed in the first direction z, the two metal layers 112 may be configured to be surrounded by a perimeter of the insulative layer 111.

As shown in FIGS. 23 and 24, the heat dissipation layer 113 may be located opposite the two metal layers 112 with respect to the insulative layer 111 in the first direction z. The heat dissipation layer 113 may be exposed from the sealing resin 50. The composition of the heat dissipation layer 113 may include copper. A dimension of the heat dissipation layer 113 in the first direction z may be larger than a dimension of the insulative layer 111 in the first direction z. As viewed in the first direction z, the heat dissipation layer 113 may be configured to be surrounded by a perimeter of the insulative layer 111. The heat dissipation layer 113 may be configured to be in contact with the insulative layer 71.

As shown in FIG. 23, the first conductive layer 121 and the second conductive layer 122 may be bonded to the base material 11. The first conductive layer 121 and the second conductive layer 122 may be individually bonded to each of the two metal layers 112 of the base material 11 via respective bonding layers 123. The bonding layer 123 is solder, for example. Alternatively, the bonding layer 123 may be made of a brazing material containing silver (Ag).

As shown in FIG. 20, each of the first conductive layer 121 and the second conductive layer 122 may overlap with the narrowing portion 831A of the hollow portion 831 of the housing 83 as viewed in the first direction z. Each of the first conductive layer 121 and the second conductive layer 122 may overlap with the heat dissipation body 84 as viewed in the first direction z.

As shown in FIGS. 20 to 23, the attachment member 88 may hold the sealing resin 50 to the heat dissipation member 80. The attachment member 88 may be made of a material containing metals. The attachment member 88 may be configured to be in contact with the top face 51 of the sealing resin 50 across the top face 51. The attachment member 88 is a leaf spring, for example.

The attachment member 88 may be located between the first signal terminal 161 and the second signal terminal 162 in the second direction x. The attachment member 88 may be configured to be attached to the housing 83 by fastening members 89 on both sides in the third direction y. The fastening member 89 is a bolt, for example.

Next, operative effects of the semiconductor device A40 will be described.

The semiconductor device A40 may include the heat dissipation member 80, the insulative layer 71 stacked on the heat dissipation member 80, the first conductive layer 121 located on the opposite side of the heat dissipation member 80 with respect to the insulative layer 71 and bonded to the insulative layer 71, and the semiconductor element 21 bonded to the first conductive layer 121. The semiconductor element 21 may be electrically connected to the first conductive layer 121. The insulative layer 71 may be located on one side of the first direction z with respect to the heat dissipation member 80. The insulative layer 71 may extend outside the first conductive layer 121 as viewed in the first direction z. Therefore, such a configuration in the semiconductor device A40 improve the insulation withstand voltage of the semiconductor device A40. The semiconductor device A40 may have a configuration in common with the semiconductor device A10, thereby achieving the same effect as the semiconductor device A10.

In the semiconductor device A40, the heat dissipation member 80 may include the housing 83 with which the insulative layer 71 is in contact. The housing 83 may include the hollow portion 831 inside the housing 83, and the inlet 832 and the outlet 833 leading to the hollow portion 831. As viewed in the first direction z, the first conductive layer 121 may overlap with the hollow portion 831. Such a configuration allows cooling water to flow into the hollow portion 831, thereby improving the cooling efficiency of the semiconductor device A40.

The hollow portion 831 of the housing 83 may include the narrowing portion 831A with the cross-sectional area that is minimum between the inlet 832 and the outlet 833 in a direction orthogonal to the first direction z. The first conductive layer 121 may overlap with the narrowing portion 831A as viewed in the first direction z. Such a configuration may increase the flow rate of cooling water in the narrowing portion 831A, thereby further improving the cooling efficiency of the semiconductor device A40.

The heat dissipation member 80 may include the heat dissipation body 84 accommodated in the narrowing portion 831A of the housing 83 and connected to the housing 83. The first conductive layer 121 may overlap with the heat dissipation body 84 as viewed in the first direction z. Such a configuration increases the contact area of the heat dissipation member 80 with cooling water, thereby improving the cooling efficiency of the semiconductor device A40.

The semiconductor devices according to the present disclosure are not limited to the embodiments described above. The specific configuration of each part of a semiconductor device according to the present disclosure may suitably be designed and changed in various manners.

The present disclosure includes the embodiments described in the following clauses.
Clause 1.

A semiconductor device comprising:
a heat dissipation member;
an insulative layer located on one side of the first direction with respect to the heat dissipation member and stacked on the heat dissipation member;
a conductive layer located on the opposite side of the heat dissipation member with respect to the insulative layer and bonded to the insulative layer; and
a semiconductor element bonded to the conductive layer,
wherein the semiconductor element is electrically connected to the conductive layer, and the insulative layer extends outside the conductive layer as viewed in the first direction.
Clause 2.

The semiconductor device according to clause 1, wherein the insulative layer is in contact with the heat dissipation member.
Clause 3.

The semiconductor device according to clause 2, wherein the insulative layer is made of a material containing resin.
Clause 4.

The semiconductor device according to clause 2, wherein a dimension of the conductive layer in the first direction is larger than a dimension of the insulative layer in the first direction.
Clause 5.

The semiconductor device according to clause 4, wherein the semiconductor element is electrically bonded to the conductive layer.
Clause 6.

The semiconductor device according to any one of clauses 2 to 5, further comprising a sealing resin covering the conductive layer and the semiconductor element.
Clause 7.

The semiconductor device according to clause 6, wherein the heat dissipation member includes:
a base portion with which the insulative layer is in contact; and
a heat dissipating portion located on the opposite side of the insulative layer with respect to the base portion and protruding in the first direction from the base portion, and the sealing resin covers at least a part of the insulative layer.
Clause 8.

The semiconductor device according to clause 7, wherein the base portion includes an outer face facing the first direction from which the heat dissipating portion protrudes, and the outer face is exposed from the sealing resin.
Clause 9.

The semiconductor device according to clause 8, wherein the base portion includes an end face facing a direction orthogonal to the first direction, and
the sealing resin overlaps with the end face as viewed in the direction orthogonal to the first direction.
Clause 10.

The semiconductor device according to clause 9, wherein the base portion includes an inner face facing opposite side of the outer face in the first direction, and the insulative layer covers the entirety of the inner face.
Clause 11.

The semiconductor device according to clause 10, wherein the insulative layer covers the end face.
Clause 12.

The semiconductor device according to clause 11, wherein the insulative layer covers the outer face.
Clause 13.

The semiconductor device according to clause 7, wherein the dimension of the insulative layer in the first direction is smaller than the dimension of the base portion in the first direction.
Clause 14.

The semiconductor device according to clause 13, further comprising a bonding layer bonding a metal layer and a conductive layer,
the metal layer is stacked on the insulative layer.
Clause 15.

The semiconductor device according to clause 6, wherein the heat dissipation member has a housing with which the insulative layer contacts,
the housing has a hollow portion located inside the housing, and an inlet and an outlet leading to the hollow portion, and
the conductive layer overlaps with the hollow portion as viewed in the first direction.
Clause 16.

The semiconductor device according to clause 15, wherein the hollow portion includes a narrowing portion having a minimum cross-sectional area in a direction orthogonal to the first direction and in a section from the inlet to the outlet, and
the conductive layer overlaps with the narrowing portion as viewed in the first direction.
Clause 17.

The semiconductor device according to clause 16, wherein the heat dissipation member has a heat dissipation body accommodated in the narrowing portion and connected to the housing, and
the conductive layer overlaps with the heat dissipation body as viewed in the first direction.

### REFERENCE NUMERALS

A10, A20, A30, A40: Semiconductor device
11: Base material
111: Insulative layer
112: Metal layer
113: Heat dissipation layer
121: First conductive layer
121A: First obverse face
122: Second support layer
122A: Second obverse face
123: Bonding layer
13: First input terminal
13A: Covered portion
13B: Exposed portion
14: Output terminal
14A: Covered portion
14B: Exposed portion
15: Second input terminal
15A: Covered portion
15B: Exposed portion
161: First signal terminal
162: Second signal terminal
171: Third signal terminal
172: Fourth signal terminal
181: Fifth signal terminal
182: Sixth signal terminal
19: Seventh signal terminal
21: Semiconductor element
21A: First element
21B: Second element
211: First electrode
212: Second electrode
213: Third electrode
214: Fourth electrode
22: Thermistor
23: Conductive bonding layer
31: First conductive member
311: Body portion
312: First bonding portion
313: First bonding portion
314: Second bonding portion
315: Second coupling portion
32: Second conductive member
321: Body portion
322: Third bonding portion
323: Third bonding portion
324: Fourth bonding portion
325: Fourth coupling portion
326: Intermediate portion
327: Beam portion
33: First conductive bonding layer
34: Second conductive bonding layer
35: Third conductive bonding layer
36: Fourth conductive bonding layer
41: First wire
42: Second wire
43: Third wire
44: Fourth wire
50: Sealing resin
51: Top face
52: Bottom face
53: First side face
54: Second side face
55: Recess
60: Control wiring
601: First wiring
602: Second wiring
61: Insulative layer
62: Wiring layer
621: First wiring layer
622: Second wiring layer
623: Third wiring layer
624: Fourth wiring layer
625: Fifth wiring layer
63: Metal layer
64: Sleeve
641: End face
68: First adhesion layer
69: Second adhesion layer
71: Insulative layer
72: Metal layer
73: Bonding layer
80: Heat dissipation member
81: Base portion
811: Inner face
812: Outer face
813: End face
82: Heat dissipating portion
83: Housing
83A: Mounting face
831: Hollow portion
831A: Narrowing portion
832: Inlet
833: Outlet
84: Heat dissipation body
88: Attachment member
89: Fastening member
z: first direction
x: second direction
y: third direction

1. A semiconductor device comprising:
a heat dissipation member;
an insulative layer located on one side of the first direction with respect to the heat dissipation member and stacked on the heat dissipation member;
a conductive layer located on the opposite side of the heat dissipation member with respect to the insulative layer and bonded to the insulative layer; and
a semiconductor element bonded to the conductive layer,
wherein the semiconductor element is electrically connected to the conductive layer, and
the insulative layer extends outside the conductive layer as viewed in the first direction.

2. The semiconductor device according to claim 1, wherein the insulative layer is in contact with the heat dissipation member.

3. The semiconductor device according to claim 2, wherein the insulative layer is made of a material containing resin.

4. The semiconductor device according to claim 2, wherein a dimension of the conductive layer in the first direction is larger than a dimension of the insulative layer in the first direction.

5. The semiconductor device according to claim 4, wherein the semiconductor element is electrically bonded to the conductive layer.

6. The semiconductor device according to claim 2, further comprising a sealing resin covering the conductive layer and the semiconductor element.

7. The semiconductor device according to claim 6, wherein the heat dissipation member includes:
a base portion with which the insulative layer is in contact; and
a heat dissipating portion located on the opposite side of the insulative layer with respect to the base portion and protruding in the first direction from the base portion, and
the sealing resin covers at least a part of the insulative layer.

8. The semiconductor device according to claim 7, wherein the base portion includes an outer face facing the first direction from which the heat dissipating portion protrudes, and
the outer face is exposed from the sealing resin.

9. The semiconductor device according to claim 8, wherein the base portion includes an end face facing a direction orthogonal to the first direction, and
the sealing resin overlaps with the end face as viewed in the direction orthogonal to the first direction.

10. The semiconductor device according to claim 9, wherein the base portion includes an inner face facing opposite side of the outer face in the first direction, and
the insulative layer covers the entirety of the inner face.

11. The semiconductor device according to claim 10, wherein the insulative layer covers the end face.

12. The semiconductor device according to claim 11, wherein the insulative layer covers the outer face.

13. The semiconductor device according to claim 7, wherein a dimension of the insulative layer in the first direction is smaller than a dimension of the base portion in the first direction.

14. The semiconductor device according to claim 13, further comprising
a metal layer stacked on the insulative layer; and
a bonding layer bonding the metal layer and the conductive layer.

15. The semiconductor device according to claim 6, wherein the heat dissipation member includes a housing with which the insulative layer is in contact,
the housing is provided with:
a hollow portion located inside the housing; and
an inlet and an outlet leading to the hollow portion, and
the conductive layer overlaps with the hollow portion as viewed in the first direction.

16. The semiconductor device according to claim 15, wherein the hollow portion includes a narrowing portion with a minimum cross-sectional area between the inlet and the outlet in a direction orthogonal to the first direction, and
the conductive layer overlaps with the narrowing portion as viewed in the first direction.

17. The semiconductor device according to claim 16, wherein the heat dissipation member includes a heat dissipation body accommodated in the narrowing portion and connected to the housing, and
the conductive layer overlaps with the heat dissipation body as viewed in the first direction.
